(19) United States
(12) Patent Application Publication
(10) Pub. No.: US 2011/0318920 A1
(43) Pub. Date: Dec. 29, 2011

(54) LOW TEMPERATURE, LONG TERM ANNEALING OF NICKEL CONTACTS TO LOWER INTERFACIAL RESISTANCE

(75) Inventors: William F. Seng, Austin, TX (US); Richard L. Woodin, Gorman, ME (US)

(73) Assignee: Fairchild Semiconductor Corporation, South Portland, ME (US)

(21) Appl. No.: 13/038,126

(22) Filed: Mar. 1, 2011

Related U.S. Application Data
(63) Continuation of application No. 11/772,623, filed on Jul. 2, 2007, now abandoned.
Application No. 11/772,623 is a division of application No. 10/807,074, filed on Mar. 23, 2004, now abandoned.

(51) Int. Cl. H01L 21/28

(52) U.S. Cl. 438/660; 257/E21.158

(57) ABSTRACT

A method of annealing semiconductor devices to form substantially ohmic contact regions between a layer of wide band-gap semiconductor material and contact areas disposed thereon includes exposing the semiconductor devices to an annealing temperature less than approximately 900 degrees Celsius for an annealing duration of greater than approximately two hours.

### CROSS-REFERENCE TO RELATED APPLICATIONS

This application is a continuation of U.S. patent application Ser. No. 11/772,623 filed Jul. 2, 2007 which is a divisional of U.S. patent application Ser. No. 10/807,074, filed Mar. 23, 2004 (now abandoned), the descriptions of which are hereby incorporated by reference.

### FIELD OF THE INVENTION

The present invention relates to methods of making semiconductor devices, and in particular to a method of lowering interfacial resistance of contacts to wide band-gap semiconductor layers in such devices.

### BACKGROUND OF THE INVENTION

Generally, most semiconductor devices are fabricated from silicon. Methods for fabricating ohmic metal-to-silicon contacts are well known. However, silicon-based devices have certain limitations, such as limited maximum operating temperatures and maximum power ratings. In order to overcome such limitations, some semiconductor devices are fabricated from wide band-gap materials, such as silicon carbide (SiC). Such wide band-gap devices are capable of operating at substantially higher maximum operating temperatures and power levels. Wide band-gap devices, however, have their own limitations. One of those limitations is the difficulty encountered in fabricating low-resistance ohmic metal contacts to the wide band-gap semiconductor material.

More particularly, the fabrication of an ohmic contact to a layer of wide band-gap semiconductor material generally requires the deposition of a contact metal, such as aluminum. Thereafter, the device must be exposed to very high temperatures, such as temperatures of 1,000 degrees C. or higher. When the contact metal is exposed to such high temperatures it is likely to melt, clump, ball and/or otherwise separate from the high band-gap semiconductor layer, thereby undesirably reducing the interfacial area between the contact metal and the layer of high band-gap semiconductor material. Such a reduction in interfacial area, in turn, causes an increase in the resistivity of the connection between the wide band-gap layer and the metal contact and otherwise adversely affects the quality and/or reproducibility of high band-gap-to-metal contacts.

Another difficulty that is encountered in fabricating low-resistance ohmic metal contacts to a wide band-gap layer is a phenomenon called spiking. Spiking occurs when metal contact material extends as a result of annealing entirely through the layer of wide band-gap semiconductor material to the substrate, thereby creating a short circuit to the semiconductor substrate. Barrier layers may be interposed between the substrate and the wide band-gap layer to prevent spiking. The use of such barrier layers, however, requires additional processing steps and generally increases the resistivity of the connection between the contact metal and the layer of wide band-gap material. Further, although effective in reducing the occurrence of spiking, barrier layers do little if anything to reduce the above-described deleterious effects of annealing.

Therefore, what is needed in the art is an improved method of forming ohmic contacts between a contact layer and a layer of wide band-gap semiconductor material.

Furthermore, what is needed in the art is a method of optimizing the process of annealing a contact material on a wide band-gap semiconductor material to thereby produce an ohmic connection between the contact material and the wide band-gap semiconductor material that has desired and/or optimized electrical characteristics.

### SUMMARY OF THE INVENTION

The present invention provides a method of long-term low-temperature annealing of semiconductor devices to form ohmic contact regions between a layer of wide band-gap semiconductor material and contact areas disposed thereon.

The present invention comprises, in one form thereof, exposing the semiconductor devices to an annealing temperature less than approximately 900 degrees Celsius for an annealing duration of greater than approximately two hours.

An advantage of the method of the present invention is that the optimum annealing duration for a given annealing temperature is determined.

Another advantage of the method of the present invention is that the optimum annealing process parameters are determined.

A further advantage of the present invention is that the annealing time required to produce a contact region that is substantially entirely ohmic in nature and having a substantially minimum resistance is determined.

A still further advantage of the present invention is that annealing beyond the point at which a contact region becomes ohmic and attains a substantially minimum value of resistance (i.e., over annealing) is reduced or avoided.

### BRIEF DESCRIPTION OF THE DRAWINGS

The above-mentioned and other features and advantages of this invention, and the manner of attaining them, will become apparent and be more completely understood by reference to the following description of one embodiment of the invention when read in conjunction with the accompanying drawings, wherein:

FIG. 1 is a partial, cross-sectional view of an exemplary wide band-gap semiconductor device having a contact layer formed thereon;

FIG. 2 is a partial, cross-sectional view of the device of FIG. 1 with after etching of the contact layer to form contact areas from the contact layer;

FIG. 3 is a partial, cross-sectional view of the device of FIG. 1 after annealing; and

FIG. 4 shows plots of current vs. voltage between two metal contacts disposed on a layer of wide band-gap semiconductor material for various durations of annealing time.

Corresponding reference characters indicate corresponding parts throughout the several views. The exemplifications set out herein illustrate one preferred embodiment of the invention, in one form, and such exemplifications are not to be construed as limiting the scope of the invention in any manner.

### DETAILED DESCRIPTION

Referring now to the drawings and particularly to FIGS. 1-3, a portion of a semiconductor device 10 is shown. Semiconductor device 10 includes a substrate 12 over which a layer of wide band-gap semiconductor material 14 has been formed. A contact layer 16 is deposited by known methods over the layer of wide band-gap material 14. As is more particularly described hereinafter, the method of the present invention optimizes the process of annealing that forms ohmic connections between contact layer 16 and the layer of wide band-gap semiconductor material 14.

Substrate 12 is a wide band-gap semiconductor material, such as, for example, silicon carbide or other wide band-gap semiconductor material having a band-gap of approximately two electron volts or greater. Substrate 12 may be doped with a conductivity type opposite the conductivity type of the overlying layer of wide band-gap semiconductor material 14 to thereby form a P-N or similar junction therebetween.

Wide band-gap semiconductor material 14 is, as described above, formed over substrate 12. Wide band-gap semiconductor material 14, such as, for example, silicon carbide or other wide band-gap semiconductor material having a band-gap of approximately two electron volts or greater, has a thickness that is determined at least in part by the end product requirements, specifications, and/or intended application of device 10.

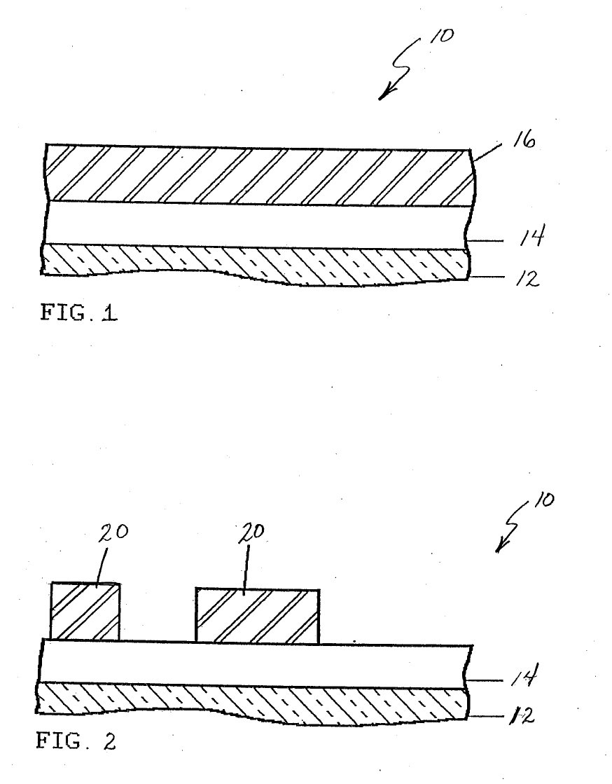

Contact layer 16, such as, for example, aluminum, zinc, nickel or other similar metal, is formed by, for example, sputtering, chemical vapor deposition, or other processes, over wide band-gap semiconductor material layer 14. Contact layer 16 and wide band-gap semiconductor material layer 14 are in substantially continuous contact. As deposited and prior to annealing, contact layer 16 forms a rectifying or otherwise non-ohmic connection to wide band-gap semiconductor material layer 14. Contact layer 16 is typically patterned and etched by known methods to expose desired portions of wide band-gap semiconductor material layer 14. Features (not shown) are then etched in the wide band-gap semiconductor material layer 14 using known methods, and to form functional circuit structures and thereby a functional semiconductor device 10. The portion or portions of contact layer 16 that remain after etching define one or more contact areas 20 (FIG. 2).

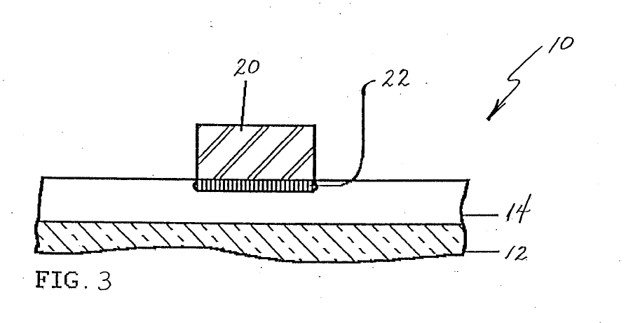

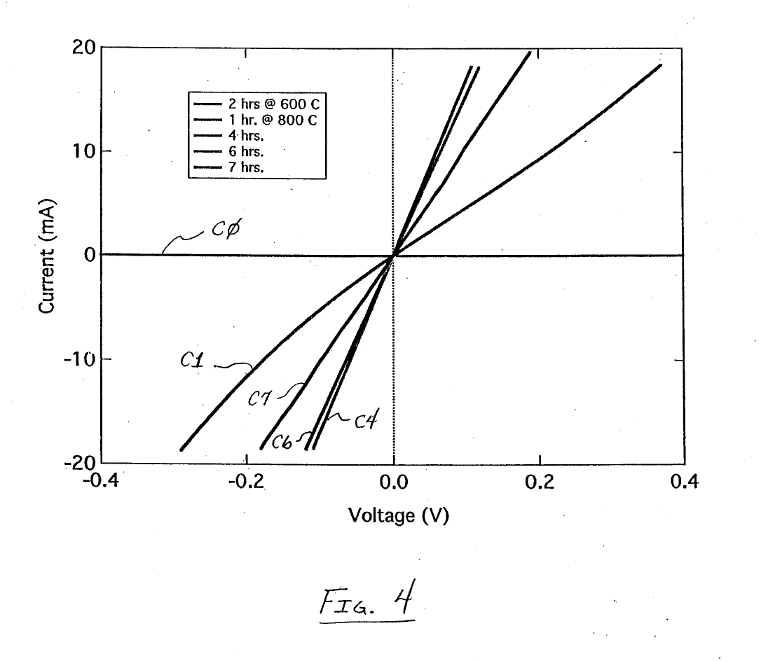

Devices 10 are then annealed to transform the electrical connection between contact area 20 and wide band-gap semiconductor material layer 14 from a connection that has primarily rectifying electrical characteristics prior to annealing to one having substantially ohmic electrical characteristics. The annealing process creates contact regions 22 (FIG. 3) between contact layer 16 and wide band-gap semiconductor material layer 14. Contact regions 22 primarily include alloys of the materials from which contact layer 16 and wide band-gap semiconductor material layer 14 are formed. The extent of the annealing reaction is at least in part dependent upon the temperature and duration of the annealing process, and determines the metallurgy of the contact regions 22. The metallurgy of contact regions 22, in turn, determines the electrical characteristics and/or quality of the connection between contact layer 16 and wide band-gap semiconductor material layer 14. Thus, the extent of the annealing reaction determines the electrical characteristics and/or quality of the connection between contact layer 16 and wide band-gap semiconductor material layer 14. An ideal or optimum connection between contact layer 16 and wide band-gap semiconductor material layer 14 is provided by a contact region 22 that is substantially entirely ohmic in nature and has a relatively low or minimum resistance.

Generally, according to one embodiment of the method of the present invention the current-versus-voltage characteristics between two spaced-apart contact regions 22 are measured and plotted after being annealed at a fixed annealing temperature for varying durations of annealing time. If desired, the process of measuring and plotting the current-versus-voltage curves is repeated at several different and fixed annealing temperatures while varying the annealing time or duration to thereby determine optimum or substantially optimum annealing time and temperature conditions. For a given annealing temperature, the optimum or substantially optimum annealing process is typically the process that produces connection regions 22 that are ohmic in nature and have the lowest resistance relative to connection regions produced by other annealing durations.

Referring now to FIG. 4, the current vs. voltage curves obtained between two spaced-apart contact regions 22 formed as a result of various annealing parameters are shown. In the exemplary embodiment of the method of the present invention, a plurality of devices 10 were formed. Devices 10 included nickel (Ni) contacts 20 having an approximate thickness of from 2400 to 2600 Angstroms. The contacts 20 were deposited via electron beam evaporation at a background pressure of approximately 1.times.10.sup.−7 Torr onto a wide band-gap semiconductor material layer 14 of 4H silicon carbide (SiC). The devices 10 were then divided into several groups of one or more devices. Each group was then subjected to respective annealing processes of correspondingly different temperatures and/or durations.

The annealing process creates two potential reaction products. In the exemplary devices described above, the annealing process creates contact regions 22 comprised of nickel silicide (Ni₂Si) and nickel carbide (Ni₃C). As discussed above, the extent of the annealing reaction determines the metallurgy of the contact regions 22 which, in turn, determines the electrical characteristics of the connection between contact layer 16 and wide band-gap semiconductor material layer 14. An ideal or optimum connection between contact layer 16 and wide band-gap semiconductor material layer 14 is provided by a contact region 22 having a metallurgy that provides a substantially ohmic contact of a relatively low or minimum resistance. The annealing process is therefore optimized to produce a contact region 22 having a metallurgy that produces such a substantially ohmic contact of relatively low or minimum resistance. In the exemplary devices, the annealing process is optimized to produce contact regions 22 having a metallurgy of Ni₂Si and Ni₃C in proportions that provide an ohmic low-resistance contact region.

After annealing, the electrical characteristics of the contact regions 22 of each group of one or more devices were measured and plotted in order to determine the optimum or near optimum annealing temperature and duration required to produce contact regions 22 that are substantially entirely ohmic and which had relatively low or minimum resistance.

More particularly, a first device or group of devices 10 were annealed at 600 degrees C. for two hours and the electrical current-versus-voltage characteristic of the contact regions 22 formed thereby were measured and plotted. The results are shown in the current-versus-voltage plot or curve C0. As curve C0 shows, the 600 degrees C. two hour annealing process did little if anything to convert contact regions 22 from their pre-annealing rectifying nature toward an ohmic characteristic, i.e., the electrical characteristics of contact regions 22 remained substantially rectifying in nature after annealing at 600 degrees C. for two hours.

A second device or group of devices 10 were annealed at 800 degrees C. for one hour, and the electrical current-versus-voltage characteristic of contact regions 22 were measured and plotted. The results are shown in the current-versus-voltage plot or curve C1. As curve C1 shows, the contact regions 22 are now slightly ohmic in nature. The slight curvature in the voltage-versus-current plot C1 reflects the Schottky-like characteristics initially exhibited by the contact regions 22 prior to annealing.

A third device or group of devices 10 were annealed at 800 degrees C. for four hours, and the electrical current-versus-voltage characteristic of contact regions 22 were measured and plotted. The results are shown in the current-versus-voltage plot or curve C4. As the curve C4 shows, the contact regions 22 are now substantially completely ohmic. The ohmic nature of contact regions 22 is shown by the substantially linear nature of the voltage-versus-current plot C4.

A third and fourth device or group of devices 10 were annealed at 800 degrees C. for 6 and 7 hours, respectively, and the electrical current-versus-voltage characteristic of the respective contact regions 22 formed thereby were measured and plotted. The results of the 6 and 7 hour anneals at 800 degrees C. are shown in the current-versus-voltage plots or curves C6 and C7, respectively. As the linear nature of curves C6 and C7 show, the contact regions 22 remain ohmic in nature. However, the slope of curve C6 is less or smaller than the slope of curve C4, and the slope of curve C7 is even smaller (i.e., less than the slope of curve C6).

In short, the slopes of the voltage-versus-current curves decrease as annealing time increases above four hours. The slopes of the voltage-versus-current curves are inversely proportional to the resistance of the corresponding connections formed by contact regions 22 between the wide band-gap semiconductor material layer 14 and the contacts 20. In other words, a decrease in or smaller slope corresponds to contact regions 22 having increased or larger resistance. Conversely, a steeper slope corresponds to contact regions 22 having reduced or lower resistance. The optimum annealing time for a given temperature corresponds to the voltage-versus-current curve having the steepest slope (i.e., the lowest resistance).

As discussed above, and as shown by curves C4, C6 and C7, the slopes of the voltage-versus-current curves decrease as annealing time increases above the four hour curve C4. Thus, the resistance of the connections between the wide band-gap semiconductor material layer 14 and the contacts 20 formed by contact regions 22 is optimum or substantially optimum after a 4 hour anneal at 800 degrees C., and undesirably increases for longer or increased annealing times.

In summary, the method of the present invention of measuring and plotting the electrical characteristics of the contact regions 22 which connect the wide band-gap semiconductor material layer 14 and contacts 20 shows that the resistance of contact regions 22 increase when annealed for more than four hours at 800 degrees C. Thus, the method of the present invention determines the optimum or substantially optimum annealing time for the given annealing temperature. As one skilled in the art will appreciate, optimum or substantially optimum annealing time and annealing temperature conditions are easily derived by repeating the above-described process of determining the optimum annealing time for different annealing temperatures.

In the embodiment shown, the wide band-gap semiconductor material is configured as silicon carbide. However, it is to be understood that the method of the present invention is equally applicable to different wide band-gap semiconductor materials, such as, for example, gallium nitride and/or aluminum nitride.

In the embodiment shown, wide band-gap semiconductor material is configured as 4H silicon carbide. However, it is to be understood that the method of the present invention is equally applicable to different poly-types of silicon carbide, such as, for example, 6H SiC and 3C—SiC.

In the embodiment shown, the method of the present invention is applied to determine optimum annealing process parameters to produce connection regions that are ohmic in nature and have relatively low or minimum resistance relative to connection regions produced by different annealing process parameters. However, it is to be understood that the method of the present invention can be alternately applied, such as, for example, to optimize annealing processes parameters to produce a connection region having a given or maximum resistance in a minimum amount of annealing time or at a minimum annealing temperature.

While the present invention has been described as having a preferred design, the invention can be further modified within the spirit and scope of this disclosure. This disclosure is therefore intended to encompass any equivalents to the structures and elements disclosed herein. Further, this disclosure is intended to encompass any variations, uses, or adaptations of the present invention that use the general principles disclosed herein. Moreover, this disclosure is intended to encompass any departures from the subject matter disclosed that come within the known or customary practice in the pertinent art and which fall within the limits of the appended claims.

We claim:

1. A method of forming a substantially ohmic contact on a layer of wide band-gap semiconductor material comprising:
depositing a nickel layer directly on said layer of wide band-gap semiconductor material; and
exposing said layer of wide band-gap semiconductor material and deposited nickel layer to an annealing temperature less than approximately 900 degrees Celsius for an annealing duration of greater than approximately two hours.

2. The method of claim 1, wherein said wide band-gap semiconductor material comprises a material having a band gap of approximately two electron volts or more.

3. The method of claim 1, wherein said wide band-gap semiconductor material comprises silicon carbide.

4. The method of claim 3, wherein said wide band-gap semiconductor material comprises n-type silicon carbide.

5. The method of claim 4, wherein said layer of metal comprises nickel.

6. The method of claim 1, wherein said annealing temperature is less than approximately 850 degrees Celsius and said annealing duration is greater than approximately 3 hours.

7. The method of claim 1, wherein said annealing temperature is approximately 800 degrees Celsius and said annealing duration is approximately four hours.
